(19) United States
(12) Patent Application Publication
(10) Pub. No.: US 2024/0315056 A1
(43) Pub. Date: Sep. 19, 2024

(54) PERIPHERAL CIRCUIT ASSEMBLIES, MEMORY SYSTEMS AND FABRICATION METHODS OF MEMORY SYSTEMS

(71) Applicant: Yangtze Memory Technologies Co., Ltd., Wuhan (CN)

(72) Inventors: Yuxuan Ren, Wuhan (CN); Yanwei Shi, Wuhan (CN); Xuelian Yu, Wuhan (CN); Hu Ding, Wuhan (CN); Lei Ren, Wuhan (CN)

(21) Appl. No.: 18/352,809

(22) Filed: Jul. 14, 2023

(30) Foreign Application Priority Data
Mar. 15, 2023 (CN) 202310270309.1

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1434

(57) ABSTRACT

The present application discloses a peripheral circuit assembly, a memory system and a fabrication method of the memory system. The peripheral circuit assembly includes a first peripheral circuit chip; a second peripheral circuit chip located on a side of the first peripheral circuit chip along a first direction, wherein one of the first peripheral circuit chip and the second peripheral circuit chip includes a low low voltage device, and the other one includes a high voltage device, and the first peripheral circuit chip or the second peripheral circuit chip further includes a controller. The memory system includes a peripheral circuit assembly including a first peripheral circuit chip and a second peripheral circuit chip, wherein one of the first peripheral circuit chip and the second peripheral circuit chip includes a low low voltage device, and the other one includes a high voltage device, and the first peripheral circuit chip or the second peripheral circuit chip further includes a controller; and at least one memory array chip that is in bonding connection with at least one of the first peripheral circuit chip and the second peripheral circuit chip along a first direction.

### CROSS-REFERENCE TO RELATED APPLICATION

This application claims priority to and the benefit of Chinese Patent Application 202310270309.1, filed on Mar. 15, 2023, which is hereby incorporated by reference in its entirety.

### TECHNICAL FIELD

Implementations of the present application relate to the technical field of semiconductors, and in particular to a peripheral circuit assembly, a memory system and a fabrication method of the memory system.

### BACKGROUND

As feature sizes of semiconductor manufacturing processes are increasingly getting smaller, the storage density of memory devices is increasingly getting higher, and a three-dimensional memory emerges as the times require. In order to increase the storage capacity of the three-dimensional memory, the number of stacked layers of a memory array chip of the three-dimensional memory is continuously increasing. In the case that the storage capacity is fixed, as the number of stacked layers of the memory array chip increases, the size of the memory array chip decreases, and a complementary metal oxide semiconductor (CMOS) in bonding connection with the memory array chip is also reduced in size simultaneously, but this affects the formation of peripheral devices.

### BRIEF DESCRIPTION OF THE DRAWINGS

Other features, purposes and advantages of the present application will become more apparent by reading the detailed description of non-limitative examples made by reference to the following figures. The figures are used for a better understanding of the scheme, but do not constitute limitations on the present application. In the figures:

FIGS. 1 to 8 are process schematic diagrams of a fabrication method of a memory system according to one example of the present application, respectively;

FIG. 9 is a structural schematic diagram of a memory system according to one example of the present application; and

FIG. 10 is a flowchart of a fabrication method of a memory system according to one example of the present application.

### DETAILED DESCRIPTION

Optimization of the formation of the CMOS of different peripheral devices is one of the urgent technical problems to be solved.

In order to better understand the present application, various aspects of the present application will be described in more detail with reference to the figures. It is understood that these detailed descriptions are only descriptions of example implementations of the present application, and are not limitations on the scope of the present application in any manner. Like reference numbers denote like elements throughout the specification. The expression “and/or” includes any or all combinations of one or more of associated listed items.

It is noted that, in the specification, the expressions, such as first, second, third and the like, are only used to distinguish one feature from another feature, instead of representing any limitation on the features, particularly instead of representing any sequential order.

For ease of description, the thicknesses, dimensions and shapes of components have been slightly adjusted in the figures. The figures are merely examples and are not drawn to scale strictly. As used herein, terms “approximately”, “about”, and similar terms, are used to represent approximation, instead of representing a degree, and are intended to describe an inherent deviation in a measured value or a calculated value as recognized by those of ordinary skill in the art.

It is also understood that expressions, such as “comprise”, “comprising”, “have”, “include”, and/or “including”, etc., are open-ended expressions, rather than close-ended expressions in the specification. They indicate the existence of the stated features, elements and/or components, but do not exclude the existence of one or more other features, elements, components and/or combinations thereof. Moreover, the expression, such as “at least one of . . . ”, appearing before a list of listed features, modifies the whole list of features, rather than an individual element therein. Furthermore, “may” is used to represent “one or more implementations of the present application” when the implementations of the present application are described. Moreover, the term “example” is intended to refer to an example or an example illustration.

Unless otherwise defined, all phrases (including engineering terms and technical terms) as used herein have the same meanings as those generally understood by those of ordinary skill in the art to which the present application pertains. It is further understood that terms as defined in common dictionaries should be interpreted as having a meaning that is consistent with their meaning in the context of the relevant art, and should not be interpreted in an idealized or overly formal sense unless otherwise stated expressly in the present application.

It should be noted that, examples and features in the examples in the present application may be combined with one another in the case of no conflicts. In addition, unless otherwise defined expressly or conflicting with the context, specific operations included in a method as set forth in the present application are not necessarily limited to an order as set forth but may be carried out in any order or in parallel. The present application will be described in detail below by reference to the figures and in conjunction with the examples.

Furthermore, in the present application, the term “layer” refers to a material portion including a region with a thickness. A layer may extend over the entirety of an underlying or overlying structure, or may have an extent less than the extent of the underlying or overlying structure. Furthermore, a layer may be a region of a homogeneous or inhomogeneous continuous structure that has a thickness less than the thickness of a continuous structure. A layer may extend horizontally, vertically, and/or along an inclined surface. A layer may include multiple sub-layers. In addition, “connection” or “joining”, when used in the present application, may represent direct contact or indirect contact between respective components, unless otherwise expressly defined or derived from the context.

In the relevant art, as the number of stacked layers of the three-dimensional memory continues to increase, the number of peripheral devices such as high voltage (HV) devices and low low voltage (LLV) devices on the CMOS also increases, and there may be a situation that the area is not enough on the CMOS. In addition, the manufacturing processes and thermal budgets of the high voltage device and the low low voltage device are different. The low low voltage device is suitable for small-scale manufacturing processes, while the high voltage device can employ lower-cost large-scale manufacturing processes, and the corresponding thermal budget of the low low voltage device is smaller than that of the high voltage device. However, since the high voltage device and the low low voltage device are formed on the same CMOS at the same time in the relevant art, the high voltage device needs to employ the same small-scale manufacturing process as the low low voltage device, and meanwhile an additional thermal budget is required to be introduced due to the presence of the high voltage device, which increases the process cost, easily results in inconsistent polysilicon heights of different devices, and is unfavorable to the performance of the low low voltage device that is sensitive to the thermal budget. In addition, in the relevant art, the controller is usually formed on a separate wafer, and is connected with the memory array chip through a circuit wiring, which not only increases the cost, but also reduces the integration and speed of the three-dimensional memory.

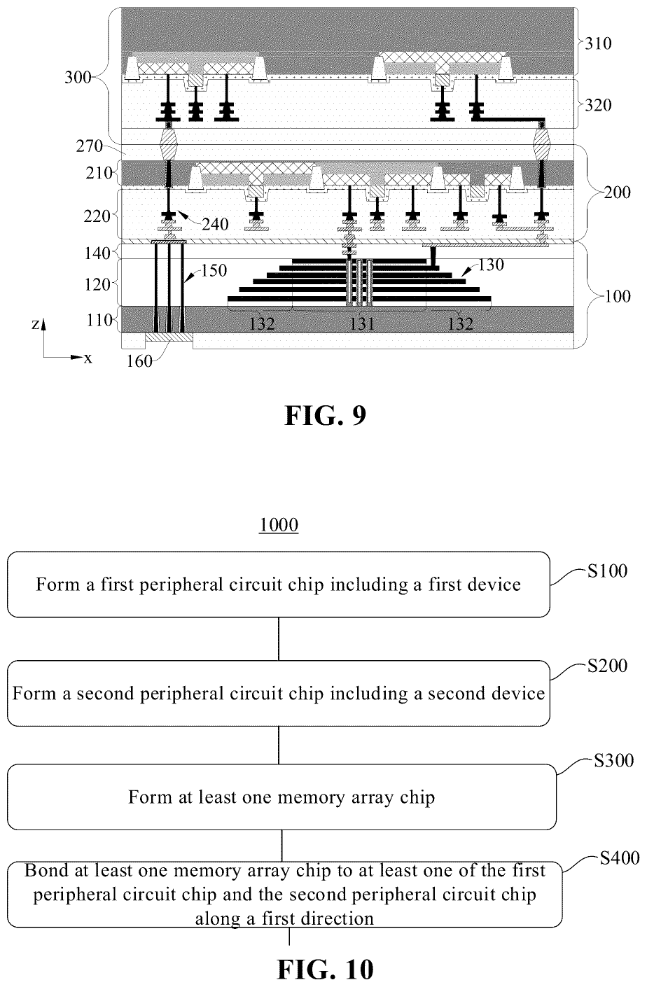

Based on this, in order to solve at least part of the above-mentioned problems, the implementations of the present application provide a peripheral circuit assembly. FIG. 9 shows a structural schematic diagram of a memory system with a peripheral circuit assembly in one of the examples of the present application. As shown in FIG. 9, the peripheral circuit assembly includes a first peripheral circuit chip 200 and a second peripheral circuit chip 300, and the second peripheral circuit chip 300 is located on a side of the first peripheral circuit chip 200 along a first direction (z direction). One of the first peripheral circuit chip 200 and the second peripheral circuit chip 300 includes a low low voltage device, and the other one includes a high voltage device, and the first peripheral circuit chip 200 or the second peripheral circuit chip 300 further includes a controller. In other words, the first peripheral circuit chip 200 includes a low low voltage device and a controller, and the second peripheral circuit chip 300 includes a high voltage device. Alternatively, the first peripheral circuit chip 200 includes a low low voltage device, and the second peripheral circuit chip 300 includes a high voltage device and a controller. Alternatively, the first peripheral circuit chip 200 includes a high voltage device and a controller, and the second peripheral circuit chip 300 includes a low low voltage device. Alternatively, the first peripheral circuit chip 200 includes a high voltage device, and the second peripheral circuit chip 300 includes a low low voltage device and a controller.

Since the low low voltage device and the high voltage device are located on different peripheral circuit chips in the implementation of the present application, even if the number of low low voltage devices and high voltage devices increases as the number of stacked layers of the memory array chip 100 of the three-dimensional memory increases, on the premise of matching the size of the memory array chip 100, the areas of the first peripheral circuit chip 200 and the second peripheral circuit chip 300 can also meet the demands for forming the low low voltage device and the high voltage device respectively, and the high voltage device and the low low voltage device no longer affect each other. In other words, the manufacturing process of the high voltage device is no longer affected by that of the low low voltage device. The high voltage device can employ a large-scale manufacturing process, which not only reduces the process cost, but also enables the polysilicon heights of the high voltage device and the low low voltage device to be unified, and the ion implantation of NP (N plus, N-type heavily doped)/PP (P plus, P-type heavily doped) of the high voltage device and the low voltage device can also be compatible. At the same time, the thermal budget of the low voltage device is no longer affected by high voltage device, and there is no need to introduce an additional thermal budget during the fabrication of the low voltage device. In addition, since the first peripheral circuit chip 200 or the second peripheral circuit chip 300 further includes a controller in the implementation of the present application, in other words, the controller and the high voltage device or the low low voltage device are integrated on the same peripheral circuit chip in the implementation of the present application, not only can the cost of forming the controller on a separate wafer be saved, but also the circuit wiring between chips can be reduced, that is, the circuit wiring between the chip where the controller is located and other chips can be saved, thereby improving the speed and integration.

It is to be noted that, the high voltage device may include, but is not limited to, at least one of a row decoder, a column decoder, a word line driver, and a bit line driver; and the low low voltage device may include, but is not limited to, an I/O circuit. The operating voltage of the high voltage device is generally greater than 3.3 V, such as 5 V-30 V. As an example, the operating voltage of the high voltage device may be 5 V, 10 V. 15 V. 20 V, 25 V or 30 V. Of course, it may also be any value between any two of the above-mentioned voltage values. The operating voltage of the low low voltage device is generally lower than 1.3 V, such as 0.9 V-1.2 V. As an example, the operating voltage of the low low voltage device may be 0.9 V. 0.95 V. 1 V. 1.05 V. 1.1 V. 1.15 V or 1.2 V. Of course, it may also be any value between any two of the above-mentioned voltage values. Those skilled in the art should understand that the above description of the operating voltage ranges of the high voltage device and the low low voltage device is for better understanding of the present solution, and does not constitute a limitation on the present application.

In some examples, the high voltage device, the low low voltage device and the controller may include, but are not limited to, at least one of a transistor, a diode, a resistor, an inductor and a capacitor.

As an example, the low low voltage device includes a transistor. In order to distinguish it from transistors of other peripheral devices, the transistor of the low low voltage device is referred to as a first transistor 290 hereinafter. As shown in FIG. 2, a first peripheral circuit chip 200 includes a first substrate 210, a low low voltage device and a first trench isolation structure 230; the low low voltage device includes a first transistor 290 at least partially located in the first substrate 210; and the first trench isolation structure 230 is at least partially located in the first substrate 210 and surrounds an active region of the first transistor 290. The presence of the first trench isolation structure 230 can achieve electrical isolation between the low low voltage device and other adjacent low low voltage devices or high voltage devices, and the first trench isolation structure 230 may be formed in the first substrate 210 by an etching process and a filling process. For example, first, a first trench may be formed on a side of the first substrate 210 by a dry etching process, a combination of dry and wet etching processes, or a patterning process; and then an insulating material may be deposited on a side of the first substrate 210 by a thin film deposition process to fill the first trench. The insulating material may be, but is not limited to, silicon dioxide, silicon nitride or silicon oxynitride. Since the insulating material covers a side of the first substrate 210 in the actual deposition process, a chemical mechanical polishing (CMP) process may be used to remove the insulating material covering other regions than the first trench on the first substrate 210 after the deposition process is finished. The first substrate 210 may be a single-layer structure or a multi-layer structure. For example, the first substrate 210 is a single-layer structure made of a semiconductor material. The semiconductor material may be, but is not limited to, monocrystalline silicon (Si), monocrystalline germanium (Ge), silicon germanium (GeSi), silicon carbide (SiC), silicon on insulator (SOI), germanium on insulator (GOI), or III-V compounds, such as gallium arsenide, etc. For another example, the first substrate 210 has a multi-layer structure in which at least two layers are made of different materials, and the first substrate 210 may be fabricated by a thin film deposition process. The above-mentioned thin film deposition process may be, but is not limited to, a physical vapor deposition (PVD) process, a chemical vapor deposition (CVD) process, an atomic layer deposition (ALD) process or any combination of the above-mentioned processes.

In some examples, the first transistor 290 may include a first source 291, a first drain 292 and a first gate structure 293, wherein the first drain 292 and the first source 291 are formed in the first substrate 210; the first gate structure 293 is located on a side of the first substrate 210 and is between the first drain 292 and the first source 291; the first gate structure 293 includes a gate insulation layer and a gate conductive layer; and the gate conductive layer is located on a side of the gate insulation layer far away from the first substrate 210. If the first transistor 290 is an N-type transistor, the first drain 292 and the first source 291 are formed in the first substrate 210 using an N-type dopant such as phosphorus (P), arsenic (As), and antimony (Sb), etc.; and if the first transistor 290 is a P-type transistor, the first drain 292 and the first source 291 are formed in the first substrate 210 using a P-type dopant such as boron (B), etc. The material of the gate insulation layer includes an insulating material such as silicon oxide, silicon nitride, silicon oxynitride, hafnium oxide, zirconium oxide, aluminum oxide, magnesium oxide, and tantalum oxide, etc., and the material of the gate conductive layer includes polysilicon, a conductive metal or a conductive alloy. As an example, the material of the gate conductive layer includes at least one of tungsten (W), titanium nitride (TiN), copper (Cu) and silver (Ag). The gate insulation layer and the gate conductive layer may be formed on a side of the first substrate 210 through a thin film deposition process.

In some examples, a low low voltage well region 294 formed by doping with a lower concentration of an N-type or P-type dopant is further formed in a partial region of the first substrate 210, and the first drain 292 and the first source 291 are formed in the low low voltage well region 294. If the first transistor 290 is an N-type transistor, a P-type doped well, i.e., a low low voltage P well, may be formed in the first substrate 210 using a P-type dopant such as boron (B), etc.; and if the first transistor 290 is a P-type transistor, an N-type doped well, i.e., a low low voltage N well, may be formed in the first substrate 210 using an N-type dopant such as phosphorus (P), arsenic (As) and antimony (Sb), etc. Each of the above-mentioned well regions may be formed in the first substrate 210 by an ion implantation or diffusion process. It is to be noted that the controller may also include a transistor, and a first trench isolation structure 230 corresponding to the transistor of the controller is formed on the first substrate 210. For case of description, the transistor of the controller is referred to as a fourth transistor 295 hereinafter, and the formation method of the fourth transistor 295 is similar to that of the first transistor 290 and is not repeated here.

Similarly, the high voltage device may also include a transistor. In order to distinguish it from the transistors of other peripheral devices such as the low low voltage device, the transistor of the high voltage device is referred to as a second transistor 350 hereinafter. As shown in FIG. 3, the second peripheral circuit chip 300 includes a second substrate 310, a high voltage device and a second trench isolation structure 330, wherein the high voltage device includes a second transistor 350 at least partially located in the second substrate 310, and the second trench isolation structure 330 is at least partially located in the second substrate 310 and surrounds an active region of the second transistor 350. The presence of the second trench isolation structure 330 can achieve electrical isolation between the high voltage device and other adjacent high voltage devices or low low voltage devices, and the second trench isolation structure 330 may be also formed in the second substrate 310 by an etching process and a filling process. The process operations of the second trench isolation structure 330 are similar to those of the first trench isolation structure 230 and are not repeated here. In addition, the second transistor 350 may include a second source 351, a second drain 352 and a second gate structure 353, wherein the second source 351 and the second drain 352 are located in the second substrate 310; the second gate structure 353 is located on a side of the second substrate 310 and is between the second drain 352 and the second source 351; and the second gate structure 353 may include a gate insulation layer and a gate conductive layer. A thickness of the gate insulation layer of the high voltage device may be greater than a thickness of the gate insulation layer of the low low voltage device, and of course, the thicknesses of both of them may also be the same, on which the present application imposes no limitation. In addition, a high voltage well region 354 formed by doping with a higher concentration of an N-type or P-type dopant may be further formed in a partial region of the second substrate 310, and the second drain 352 and the second source 351 are formed in the high voltage well region 354.

In some examples, the first peripheral circuit chip 200 and/or the second peripheral circuit chip 300 further includes a low voltage device. In other words, the first peripheral circuit chip 200 or the second peripheral circuit chip 300 includes a low voltage device. Alternatively, the first peripheral circuit chip 200 and the second peripheral circuit chip 300 include low voltage devices at the same time.

As an example, the first peripheral circuit chip 200 includes a low low voltage device, a controller and at least one low voltage device, and the second peripheral circuit chip 300 includes a high voltage device and at least one other low voltage device. The controller is located on a side of the low low voltage device and the low voltage device along a second direction (x direction) perpendicular to the first direction. Of course, the first peripheral circuit chip 200 may also include a low low voltage device and at least one low voltage device, and the second peripheral circuit chip 300 includes a controller, a high voltage device and at least one other low voltage device. Alternatively, the first peripheral circuit chip 200 includes a low low voltage device and a controller, and the second peripheral circuit chip 300 includes a high voltage device and a low voltage device. Alternatively, the first peripheral circuit chip 200 includes a low low voltage device and a low voltage device, and the second peripheral circuit chip 300 includes a high voltage device and a controller. The above-mentioned low voltage device may include, but is not limited to, a page buffer or a logic device, and the operating voltage of the low voltage device is generally between 1.3 V and 3.3 V. As an example, the operating voltage of the low voltage device may be 1.3 V, 1.8 V, 2.3 V. 2.8 V or 3.3 V. Of course, it may be any value between any two of the above-mentioned voltage values. Those skilled in the art should understand that the above description of the operating voltage ranges of the low voltage device is for better understanding of the present solution and does not constitute a limitation on the present application.

In some examples, the low voltage device may include, but is not limited to, at least one of a transistor, a diode, a resistor, an inductor, and a capacitor. As an example, each of the first peripheral circuit chip 200 and the second peripheral circuit chip 300 includes a low voltage device and a third trench isolation structure 420, and each of the low voltage device of the first peripheral circuit chip 200 and the low voltage device of the second peripheral circuit chip 300 may include a transistor. In order to distinguish it from transistors of other peripheral devices such as a low low voltage device and a high voltage device, the transistor of the low voltage device is referred to as a third transistor 410 hereinafter. The third transistor 410 and the third trench isolation structure 420 of the first peripheral circuit chip 200 are at least partially located in the first substrate 210, and the third trench isolation structure 420 surrounds an active region of the corresponding third transistor 410. The third transistor 410 and the third trench isolation structure 420 of the second peripheral circuit chip 300 are at least partially located in the second substrate 310, and the above-mentioned third trench isolation structure 420 surrounds the active region of the corresponding third transistor 410. The process operations of the third transistor 410 and the third trench isolation structure 420 are similar to those above, which are not repeated here.

In some examples, as shown in FIGS. 2 and 6, the first peripheral circuit chip 200 further includes a first interconnection layer 220 and a first connection structure 240, wherein the first connection structure 240 penetrates through the first substrate 210 and the first interconnection layer 220; the first interconnection layer 220 includes a first insulation layer 260 covering the first substrate 210 and the transistor, and a first interconnection structure 250 located in the first insulation layer 260; and the first interconnection structure 250 is connected with the transistor. The above-mentioned transistor may be at least one of the first transistor 290, the third transistor 410 and the fourth transistor 295. The first insulation layer 260 may include a plurality of interlayer insulation layers stacked sequentially along the first direction. The first interconnection structure 250 contacts with the gate structure, the source or the drain of the above-mentioned transistor at one end, and contacts with the first connection structure 240 or penetrates through the first insulation layer 260 at the other end. The first connection structure 240 includes a second interconnection structure 241 located in the first interconnection layer 220, and a first interconnection via structure 242 located in the first substrate 210. The first insulation layer 260 may be fabricated by a thin film deposition process. The material of the first insulation layer 260 may include, but is not limited to, an insulating material such as silicon oxide, silicon nitride and/or silicon oxynitride, etc. The materials of the first interconnection structure 250 and the first connection structure 240 may include, but are not limited to, at least one of tungsten, cobalt, copper, aluminum, and silicide.

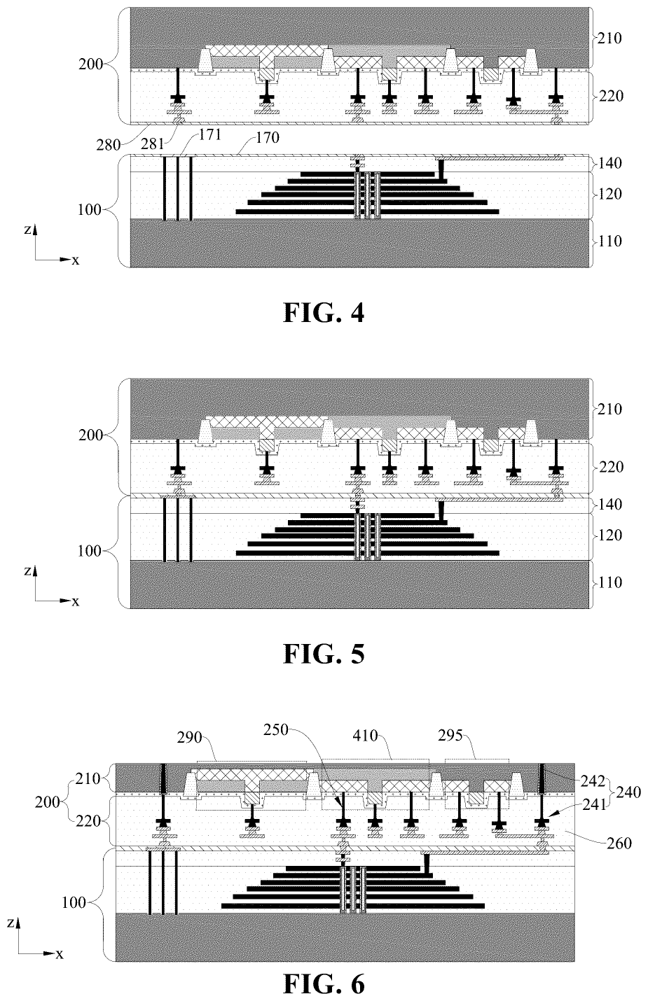

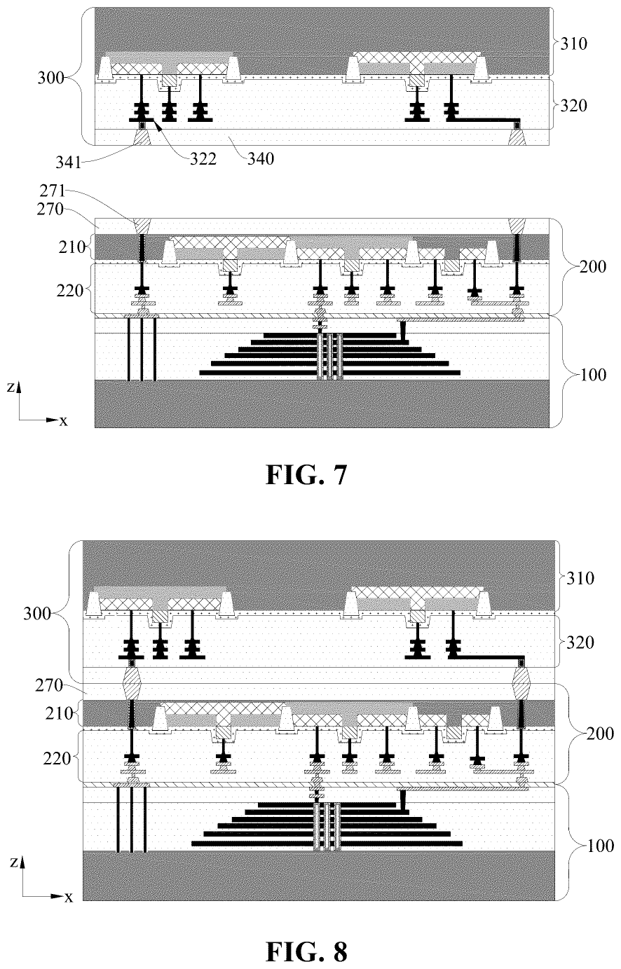

In some examples, as shown in FIGS. 4 and 7, the first peripheral circuit chip 200 may further include a first bonding layer 270 and a second bonding layer 280, wherein the first bonding layer 270 is located on a side of the first substrate 210 facing away from the first interconnection layer 220; the second bonding layer 280 is located on a side of the first interconnection layer 220 facing away from the first substrate 210; first bonding contacts 271 are formed in the first bonding layer 270, contact with the first connection structure 240 at one end, and penetrate through the first bonding layer 270 at the other end; and second bonding contacts 281 are formed in the second bonding layer 280, contact with the first connection structure 240 at one end, and penetrate through the second bonding layer 280 at the other end. The materials of the first bonding layer 270 and the second bonding layer 280 may include, but are not limited to, insulating materials such as silicon oxide, silicon nitride and/or silicon oxynitride, etc. The materials of the first bonding contacts 271 and the second bonding contacts 281 may include, but are not limited to, at least one of tungsten, cobalt, copper, aluminum, and silicide.

In some examples, as shown in FIG. 3, the second peripheral circuit chip 300 further includes a second interconnection layer 320 which covers the second substrate 310 and the transistor. The above-mentioned transistor may be the second transistor 350 and/or the third transistor 410. The second interconnection layer 320 may include a second insulation layer 321 covering the second substrate 310 and the above-mentioned transistor, and a third interconnection structure 322 located in the second insulation layer 321, wherein the third interconnection structure 322 contacts with the gate structure, the source or the drain of the above-mentioned transistor of the second peripheral circuit chip 300 at one end, and penetrates through the second insulation layer 321 at the other end. The second insulation layer 321 may be fabricated by a thin film deposition process. The material of the second insulation layer 321 may include, but is not limited to, an insulating material such as silicon oxide, silicon nitride and/or silicon oxynitride, etc. The material of the second interconnection structure 241 may include, but is not limited to, at least one of tungsten, cobalt, copper, aluminum, and silicide.

In some examples, as shown in FIG. 7, the second peripheral circuit chip 300 may further include a third bonding layer 340, wherein the third bonding layer 340 is located on a side of the second interconnection layer 320 facing away from the second substrate 310; and third bonding contacts 341 are formed in the third bonding layer 340, contact with the third interconnection structure 322 at one end, and penetrate through the third bonding layer 340 at the other end. The material of the third bonding layer 340 may include, but is not limited to, an insulating material such as silicon oxide, silicon nitride and/or silicon oxynitride, etc., and the material of the third bonding contacts 341 may include, but is not limited to, at least one of tungsten, cobalt, copper, aluminum, and silicide.

In some examples, as shown in FIGS. 7 and 8, the first peripheral circuit chip 200 is bonded to a side of the second peripheral circuit chip 300. As an example, the first bonding layer 270 described above may be bonded to the third bonding layer 340, and there is one-to-one correspondence between the first bonding contacts 271 and the third bonding contacts 341. In other words, after the first bonding layer 270 and the third bonding layer 340 are in bonding connection, a side of the first bonding layer 270 facing away from the first substrate 210, i.e., a first bonding surface, overlaps with a side of the third bonding layer 340 facing away from the second substrate 310, i.e., a third bonding surface, and the first bonding contacts 271 contact with the corresponding third bonding contacts 341.

In addition, considering that the number of high voltage devices, low voltage devices and low low voltage devices will increase as the number of stacked layers of the memory array chip 100 of the three-dimensional memory increases continuously, in order to be able to meet the demands, the peripheral circuit assembly may further include the third peripheral circuit chip that includes a low voltage device. The third peripheral circuit chip may include all of the low voltage devices, of course, it may also include part of the low voltage devices, and the rest of the low voltage devices may be disposed on the first peripheral circuit chip 200 and/or the second peripheral circuit chip 300. It is to be noted that the structure of the third peripheral circuit chip is similar to the structures of the first peripheral circuit chip 200 and the second peripheral circuit chip 300 and is not repeated here. The number of the third peripheral circuit chips may be one or a plurality. In the case that the peripheral circuit assembly includes a plurality of third peripheral circuit chips, the plurality of third peripheral circuit chips are sequentially disposed along the first direction (z direction).

FIG. 9 shows a structural schematic diagram of a memory system in one of the examples of the present application. As shown in FIG. 9, an implementation of the present application further provides a memory system, which includes at least one memory array chip 100 and the above-mentioned peripheral circuit assembly. At least one memory array chip 100 is in bonding connection with at least one of the first peripheral circuit chip 200 and the second peripheral circuit chip 300 along the first direction. The peripheral circuit assembly includes the first peripheral circuit chip 200 and the second peripheral circuit chip 300 located on a side of the first peripheral circuit chip 200 along the first direction. One of the first peripheral circuit chip 200 and the second peripheral circuit chip 300 includes a low low voltage device, and the other one includes a high voltage device. The first peripheral circuit chip 200 or the second peripheral circuit chip 300 further includes a controller.

By disposing the low low voltage device and the high voltage device on the first peripheral circuit chip 200 and the second peripheral circuit chip 300 respectively, and bonding the first peripheral circuit chip 200 and/or the second peripheral circuit chip 300 to at least one memory array chip 100, the implementation of the present application can not only dispose the low low voltage device, the high voltage device and the controller on the first peripheral circuit chip 200 or the second peripheral circuit chip 300 located on a side of the memory array chip 100, which increases the number of stacked layers, i.e., the storage density, of the memory array chip 100 without affecting the size of the memory system along a direction vertical to stacking of the memory array chip 100, thereby achieving the compatibility between the high storage density and the small size of the memory system, but also can locate the low low voltage device and the high voltage device on different peripheral circuit chips respectively, such that the high voltage device and the low low voltage device no longer affect each other. In other words, the manufacturing process of the high voltage device is no longer affected by that of the low low voltage device, the polysilicon heights of the high voltage device and the low low voltage device can also be unified, and the NP/PP ion implantation of the high voltage device and the low voltage device can also be compatible. The high voltage device can employ the large-scale manufacturing process to reduce the process cost; meanwhile, a thermal budget of the low voltage device is no longer affected by the high voltage device, and there is no need to introduce an additional thermal budget during the fabrication of the low voltage device. In addition, since the controller and the high voltage device or the low low voltage device are integrated on the same peripheral circuit chip in the implementations of the present application, not only can the cost of forming the controller on a separate wafer be saved, but also the circuit wiring between chips can be reduced, that is, the circuit wiring between the chip where the controller is located and other chips can be saved, thereby improving the speed and integration.

In some examples, the first peripheral circuit chip 200 is in bonding connection with a side of the memory array chip 100, and the second peripheral circuit chip 300 is in bonding connection with a side of the first peripheral circuit chip 200 far away from the memory array chip 100. Of course, the first peripheral circuit chip 200 and the second peripheral circuit chip 300 may also exchange positions. In other words, the second peripheral circuit chip 300 is in bonding connection with a side of the memory array chip 100, and the first peripheral circuit chip 200 is in bonding connection with a side of the second peripheral circuit chip 300 far away from the memory array chip 100. Alternatively, the memory array chip 100 is located between the first peripheral circuit chip 200 and the second peripheral circuit chip 300. In other words, the first peripheral circuit chip 200 is in bonding connection with a side of the memory array chip 100, and the second peripheral circuit chip 300 is in bonding connection with a side of the memory array chip 100 far away from the first peripheral circuit chip 200.

In some examples, the first peripheral circuit chip 200 and/or the second peripheral circuit chip 300 further includes a low voltage device. In other words, the first peripheral circuit chip 200 or the second peripheral circuit chip 300 includes a low voltage device. Alternatively, the first peripheral circuit chip 200 and the second peripheral circuit chip 300 include low voltage devices at the same time.

In some examples, considering that the number of high voltage devices, low voltage devices and low low voltage devices will increase as the number of stacked layers of the memory array chip 100 of the three-dimensional memory increases continuously, in order to meet the demands, the peripheral circuit assembly may further include a third peripheral circuit chip that may be in bonding connection with a side of the memory array chip 100, the first peripheral circuit chip 200 or the second peripheral circuit chip 300. The number of the third peripheral circuit chips may be one or a plurality. In the case that the peripheral circuit assembly includes a plurality of third peripheral circuit chips, the plurality of third peripheral circuit chips are sequentially disposed along the first direction (z direction). The third peripheral circuit chip may include all of the low voltage devices, of course, it may also include part of the low voltage devices, and the rest of the low voltage devices may be disposed on the first peripheral circuit chip 200 and/or the second peripheral circuit chip 300.

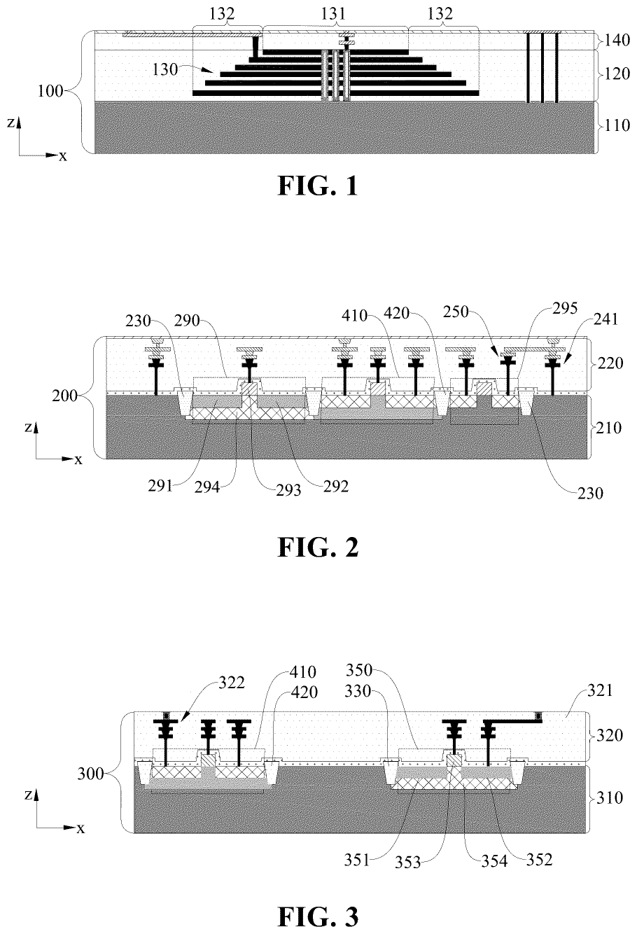

In some examples, as shown in FIG. 1, the memory array chip 100 includes a semiconductor layer 110 and a third insulation layer 120 located on a side of the semiconductor layer 110 along the first direction. A stack structure 130 is disposed in the third insulation layer 120 and includes a connection region 132 and a core region 131 formed with a plurality of channel structures. The connection region 132 is located on at least a side of the core region 131. The channel structures penetrate through the stack structure 130 along the first direction (z direction). The connection region 132 may be a step structure, or a non-step structure. For example, in the case of a staircase contact (SCT) architecture, the connection region 132 does not need to be in a staircase shape. The stack structure 130 includes gate layers and insulation layers stacked alternately along a stacking direction, i.e., the first direction. The gate layers and the insulation layers may be disposed in pairs or may not be disposed in pairs. As an example, the stack structure 130 may include, but is not limited to, 64, 128, or more than 128 pairs of gate layers and insulation layers, on which the present application imposes no limitation. The higher the number of stacked layers of the gate layers and the insulation layers is, the higher the integration of the memory array chip 100 is, in other words, the higher the unit storage density of the memory array chip 100 is.

The channel structure includes a function layer and a channel layer, each of which may be formed through a thin film deposition process, which may be, but is not limited to, a physical vapor deposition (PVD) process, a chemical vapor deposition (CVD) process, an atomic layer deposition (ALD) process or any combination of the above-mentioned processes. Further, the function layer may include a blocking layer, a charge trapping layer and a tunneling layer sequentially disposed along a second direction (x direction), and the second direction is perpendicular to the first direction, that is, perpendicular to the stacking direction of the stack structure 130. The materials of the blocking layer and the tunneling layer may be, but are not limited to, silicon oxide, and the material of the charge trapping layer may be, but is not limited to, silicon nitride. In other words, the function layer may have an ONO structure. The material of the channel layer may be, but is not limited to, a semiconductor material such as amorphous silicon, polysilicon, or monocrystalline silicon, etc.

It is to be noted that part of the function layer and the channel layer corresponding to the gate layer and a part of the gate layer together constitute a memory cell. A plurality of memory cells are connected in series along the stacking direction of the stack structure 130, i.e., the first direction (z direction) to form a memory string. The memory cells located in the same row, that is, distributed along the second direction (x direction), may be connected to the same word line, and the rest of the gate layer may be used as a word line for a plurality of memory cells in the corresponding memory string. Each memory string, that is, the memory cells in the same column, may be connected to the same bit line (not shown). Under the control of a voltage of the corresponding word line, carriers in the channel layer of the memory cell enter the charge trapping layer of the function layer, or the carriers in the charge trapping layer of the function layer return back to the channel layer, thereby achieving programing or erasing of the memory cell.

In some examples, as shown in FIGS. 1 and 9, the memory array chip 100 may further include a third interconnection layer 140 and a second connection structure 150 in addition to the semiconductor layer 110 and the third insulation layer 120. The third interconnection layer 140 is disposed on a side of the third insulation layer 120 facing the first peripheral circuit chip 200. The stack structure 130 is connected with the first peripheral circuit chip 200 through the third interconnection layer 140. A side of the semiconductor layer 110 far away from the first peripheral circuit chip 200 is provided with a pad structure 160. The second connection structure 150 is connected with the pad structure 160 at one end and connected with the first peripheral circuit chip 200 sequentially through the semiconductor layer 110, the third insulation layer 120 and the third interconnection layer 140 at the other end.

In order to shorten the wiring to reduce the cost and increase the transmission speed, in the case that the first peripheral circuit chip 200 and/or the second peripheral circuit chip 300 includes the low voltage device, the low voltage device is disposed corresponding to the core region 131, and the high voltage device is disposed corresponding to the connection region 132. As an example, the low voltage device includes a page buffer that is connected with a bit line to apply a bit line voltage to the bit line, wherein the bit line voltage corresponds to data DATA to be programmed, and the data DATA may include multi-bit data. In a read operation, the page buffer may sense data DATA stored in the selected memory cells through the bit line and output the sensed data DATA to an I/O circuit. The high voltage device may include a word line driver that is connected with a word line through a word line contact to apply a word line voltage to the word line, thereby performing an erase operation on the memory cells corresponding to the word line. As can be seen from the above, the page buffer is connected with the bit line, and the bit line contacts with the channel structure; that is, the bit line is located within the core region 131, the word line driver is connected to the word line through the word line contact, and the word line contact is located in the connection region 132. As such, the wiring is the shortest in an implementation of the present application by disposing the low voltage device and the high voltage device corresponding to the core region 131 and the connection region 132 respectively; in other words, by substantially aligning the low voltage device with the core region 131 and the high voltage device with the connection region 132 along the first direction, so that not only the wiring cost can be reduced, but also the transmission rate can be increased.

In some examples, the first peripheral circuit chip 200 is in bonding connection with a side of the memory array chip 100, and the second peripheral circuit chip 300 is in bonding connection with a side of the first peripheral circuit chip 200 far away from the memory array chip 100. The first peripheral circuit chip 200 includes a first substrate 210, a low low voltage device, a controller, a first interconnection structure 250 and a first connection structure 240. As shown in FIGS. 2, 6 and 9, the low low voltage device includes a first transistor 290, the controller includes a fourth transistor 295, and both the first transistor 290 and the fourth transistor 295 are at least partially located in the first substrate 210. The active region of each of the first transistor 290 and the fourth transistor 295 is surrounded by the first trench isolation structure 230. The first interconnection layer 220 covers sides of the first substrate 210, the first transistor 290 and the fourth transistor 295 facing the memory array chip 100. The first transistor 290 and/or the fourth transistor 295 are connected with the memory array chip 100 through the first interconnection layer 220. The first connection structure 240 is connected with the second peripheral circuit chip 300 at one end and connected with the memory array chip 100 through the first substrate 210 and the first interconnection layer 220 at the other end. Further, in the case that the first peripheral circuit chip 200 includes a low voltage device, a third transistor 410 of the low voltage device is further disposed on the first substrate 210.

In some examples, as shown in FIGS. 6 and 9, the first interconnection layer 220 includes a first insulation layer 260 and a first interconnection structure 250, wherein the first insulation layer 260 covers sides of the first substrate 210 and the transistor facing the memory array chip 100. The first interconnection structure 250 is located in the first insulation layer 260, connected with at least one of the first transistor 290, the third transistor 410 and the fourth transistor 295 at one end, and connected with the first connection structure 240 or the memory array chip 100 at the other end. The first insulation layer 260 may include a plurality of interlayer insulation layers stacked sequentially along the first direction. The first interconnection structure 250 contacts with the gate structure, the source or the drain of the above-mentioned transistor at one end, and contacts with the first connection structure 240 or penetrates through the first insulation layer 260 at the other end.

In some examples, as shown in FIGS. 3 and 7, the second peripheral circuit chip 300 includes a second substrate 310, a high voltage device and a second interconnection layer 320. Further, the second peripheral circuit chip 300 may include a low voltage device. The high voltage device includes a second transistor 350, and the low voltage device includes a third transistor 410. The second transistor 350 and the third transistor 410 are at least partially located in the second substrate 310. The second interconnection layer 320 covers sides of the second substrate 310, the second transistor 350 and the third transistor 410 facing the first peripheral circuit chip 200. The second transistor 350 and/or the third transistor 410 are connected with the first peripheral circuit chip 200 through the second interconnection layer 320. Further, the second interconnection layer 320 may include a second insulation layer 321 covering the second substrate 310, the second transistor 350 and the third transistor 410 and a third interconnection structure 322 located in the second insulation layer 321. The third interconnection structure 322 contacts with the gate structure, the source or the drain of the third transistor 410 and/or the second transistor 350 of the second peripheral circuit chip 300 at one end and is connected with the first connection structure 240 of the first peripheral circuit chip 200 through the second insulation layer 321 at the other end.

FIGS. 1 to 8 respectively show the process schematic diagrams of a fabrication method of a memory system in one of the examples of the present application, and FIG. 10 is a flowchart of a fabrication method of the memory system according to one implementation of the present application. As shown in FIG. 10, an implementation of the present application also provides a fabrication method of the memory system. The fabrication method 1000 includes:
S100, forming a first peripheral circuit chip 200 including a first device (see FIG. 2);
S200, forming a second peripheral circuit chip 300 (see FIG. 3) including a second device, wherein one of the first device and the second device includes a low low voltage device and the other one includes a high voltage device, and the first device or the second device further includes a controller;
S300, forming at least one memory array chip 100 (see FIG. 1); and
S400, bonding at least one memory array chip 100 to at least one of the first peripheral circuit chip 200 and the second peripheral circuit chip 300 along a first direction (see FIG. 9), wherein the second peripheral circuit chip 300 is located on a side of the first peripheral circuit chip 200 along the first direction.

Various operations in the method of fabricating the semiconductor device in the examples of the present application are introduced below in details.

### S100

In S100, a first peripheral circuit chip 200 including a first device is formed, wherein the first device may include a controller or a low voltage device in addition to a low low voltage device or a high voltage device. The high voltage device may include, but is not limited to, at least one of a row decoder, a column decoder, a word line driver and a bit line driver. The low low voltage device may include, but is not limited to, an I/O circuit. The low voltage device may include, but is not limited to, a page buffer or a logic device.

In some examples, the first device includes a low low voltage device including a first transistor 290 and a controller including a fourth transistor 295. Further, as shown in FIGS. 2 and 6, S100 may include: forming a first transistor 290 and a fourth transistor 295 on a first substrate 210, wherein the first transistor 290 and the fourth transistor 295 are at least partially located in the first substrate 210; forming, on the first substrate 210, a plurality of first trench isolation structures 230 surrounding active regions of the first transistor 290 and the fourth transistor 295; forming a first interconnection layer 220 on the first substrate 210, wherein the first interconnection layer 220 covers a side of the first substrate 210 where the first transistor 290 and the fourth transistor 295 are formed and sides of the first transistor 290 and the fourth transistor 295 far away from the first substrate 210. A second interconnection structure 241 penetrating through the first interconnection layer 220 is formed in the first interconnection layer 220, and a first interconnection via structure 242 corresponding to the second interconnection structure 241 and penetrating through the first substrate 210 is formed in the first substrate 210. First connection structure 240 includes the first interconnection structure 250 and the first interconnection via structure 242.

In some examples, the first transistor 290 may be formed on the first substrate 210 by the following operations: forming a low low voltage well region 294 in the first substrate 210, for example, if the transistor is an N-type transistor, then an ion implantation or diffusion process may be used to form a P-type doped well, i.e., a low low voltage P well, in the first substrate 210, and a dopant may be a low concentration of P-type dopant such as boron (B), etc.; and if the transistor is a P-type transistor, then an ion implantation or diffusion process may be used to form an N-type doped well, i.e., a low low voltage N well, in the first substrate 210, and a dopant may be a low concentration of N-type dopant such as phosphorus (P), arsenic (As) and antimony (Sb), etc. A first drain 292 and a first source 291 are formed in the low low voltage well region 294; if the transistor is an N-type transistor, then the first drain 292 and the first source 291 are formed in the first substrate 210 using an N-type dopant such as phosphorus (P), arsenic (As) and antimony (Sb), etc.; and if the transistor is a P-type transistor, the first drain 292 and the first source 291 is formed in the first substrate 210 using a P-type dopant such as boron (B), etc. A first gate structure 293 including a gate insulation layer and a gate conductive layer is formed on a side of the first substrate 210. For example, the gate insulation layer may be formed on a side of the first substrate 210 through a thin film deposition process, and part of the gate insulation layer is removed through an etching process, such that the rest of the gate insulation layer is located between the first source 291 and the first drain 292. The gate conductive layer is formed on a side of the gate insulation layer facing away from the first substrate 210 through a thin film deposition process, and part of the gate conductive layer is removed through an etching process, such that the rest of the gate conductive layer is located between the first source 291 and the first drain 292 and covers the gate insulation layer. The material of the gate insulation layer includes a dielectric material such as silicon oxide, silicon nitride, silicon oxynitride, hafnium oxide, zirconium oxide, aluminum oxide, magnesium oxide, and tantalum oxide, etc., and the material of the gate conductive layer includes polysilicon, a conductive metal or a conductive alloy. As an example, the material of the gate conductive layer includes at least one of tungsten (W), titanium nitride (TiN), copper (Cu) and silver (Ag). It is to be noted that the first source 291 and the first drain 292 of the first transistor 290 may also be directly formed in the first substrate 210; in other words, the above-mentioned operations may not include the operation of forming the low low voltage well region 294. The method of forming the fourth transistor 295 on the first substrate 210 is similar to the method of forming the first transistor 290 above, and is not repeated here.

In some examples, the first device may further include a low voltage device that includes a third transistor 410. The first interconnection layer 220 includes a first insulation layer 260 covering the first substrate 210, the first transistor 290, the third transistor 410 and the fourth transistor 295 and a first interconnection structure 250 located in the first insulation layer 260, and the first interconnection structure 250 is connected with the first transistor 290, the third transistor 410 and/or the fourth transistor 295. The first insulation layer 260 may include a plurality of interlayer insulation layers stacked sequentially along a first direction. The first interconnection structure 250 contacts with a gate structure, a source or a drain of the above-mentioned transistor at one end, and contacts with the first connection structure 240 or penetrates through the first insulation layer 260 at the other end.

### S200

In S200, a second peripheral circuit chip 300 including a second device is formed, wherein one of the first device and the second device includes a high voltage device, and the other one includes a low low voltage device. In addition, the second device may further include a controller or a low voltage device.

In some examples, the second device includes a high voltage device. As shown in FIG. 3, S200 may include: forming a second transistor 350 of a high voltage device on a second substrate 310, wherein the second transistor 350 is at least partially located in the second substrate 310; forming a second trench isolation structure 330 surrounding an active region of the second transistor 350 on the second substrate 310; and forming a second interconnection layer 320 on the second substrate 310, wherein the second interconnection layer 320 covers a side of the second substrate 310 where the second transistor 350 is formed and a side of the second transistor 350 far away from the second substrate 310. It is to be noted that the formation method of the second transistor 350 of the high voltage device is similar to the formation method of the first transistor 290 of the low low voltage device above, and is not repeated here. In addition, if the second transistor 350 of the high voltage device includes a well region, then the well region is a high voltage well region 354 formed by doping with a higher concentration of an N-type or P-type dopant, and a second source 351 and a second drain 352 of the high voltage device are formed in the high voltage well region 354.

In some examples, the second device may further include a low voltage device that includes a third transistor 410. The second interconnection layer 320 may include a second insulation layer 321 covering the second substrate 310 and the second and third transistors 350 and 410, and a third interconnection structure 322 located in the second insulation layer 321. The third interconnection structure 322 contacts with a gate structure, a source or a drain of the above-mentioned transistor of the second peripheral circuit chip 300 at one end, and penetrates through the second insulation layer 321 at the other end.

### S300

In S300, a memory array chip 100 is formed, wherein the number of the memory array chips 100 may be one or a plurality.

In some examples, S300 may include: forming a laminated structure on a side of a third substrate (not shown), wherein the laminated structure includes insulation layers and sacrificial layers stacked alternately along a first direction; forming, in the laminated structure, a channel structure at least penetrating through the laminated structure; replacing the sacrificial layers with gate layers to form a stack structure 130; and removing the third substrate to form a semiconductor layer 110 on a side of the stack structure. The insulation layers and the sacrificial layers may be disposed in pairs or may not be disposed in pairs. For example, the laminated structure may include, but is not limited to, 64, 128 or more than 128 pairs of insulation layers and sacrificial layers. As an example, the insulation layer is a silicon oxide layer, and the sacrificial layer is a silicon nitride layer.

In some examples, the channel structure may be formed by the following operations: along a stacking direction of the laminated structure, i.e., the first direction, forming a plurality of channel holes on a side of the laminated structure facing away from the third substrate, the channel holes penetrating through the laminated structure and extending at least to the third substrate, wherein the channel holes may be formed by a dry etching process, a combination of dry and wet etching processes, or a patterning process, and wherein the patterning process includes photolithography, cleaning and chemical mechanical polishing processes; forming blocking layers on inner walls of the channel holes to block the outflow of charges; forming charge trapping layers on sides of the blocking layers facing away from the inner walls of the channel holes to store charges; forming tunneling layers on sides of the charge trapping layers facing away from the blocking layers; forming channel layers on sides of the tunneling layers facing away from the charge trapping layers to transport the required carriers, i.e., electrons or holes; filling dielectric layers within hole spaces surrounded by the channel layers; and forming channel plugs contacting with the channel layers on sides of the filled dielectric layers facing away from the third substrate.

It is to be noted that those ordinarially skilled in the art should understand that, the formation positions of the function layers on the inner walls of the channel holes may be controlled according to different architectures of the memory system, without departing from the teaching of the present application. In other words, the function layers may be formed on sidewalls of the channel holes extending along the first direction (z direction) and may also be formed on the sidewalls and bottom surfaces of the channel holes extending along the second direction (x direction), on which the present application imposes no limitation. In addition, in order to reduce structure stress, air gaps may be formed in the filled dielectric layers by controlling corresponding parameters in the channel filling process.

In some examples, as shown in FIGS. 1, 8 and 9, S300 may further include: forming a second connection structure 150 penetrating through the semiconductor layer 110 and the third insulation layer 120; forming a third interconnection layer 140 on a side of the stack structure 130 facing away from the semiconductor layer 110; forming a fourth interconnection structure penetrating through the third interconnection layer 140 in the third interconnection layer 140, wherein the fourth interconnection structure is connected with the gate layers of the stack structure 130; and forming a pad structure 160 penetrating through the semiconductor layer 110 on a side of the semiconductor layer 110 facing away from the third insulation layer 120, wherein the pad structure 160 contacts with the second connection structure 150.

### S400

In S400, at least one memory array chip 100 is bonded to at least one of the first peripheral circuit chip 200 and the second peripheral circuit chip 300 along the first direction. The above-mentioned bonding may refer to any one of hybrid bonding, anodic bonding, fusion bonding, transfer bonding, adhesive bonding and eutectic bonding. It is to be noted that, the first peripheral circuit chip 200 and the second peripheral circuit chip 300 may be bonded to each other, and one of them is bonded to the memory array chip 100. Alternatively, two sides of the memory array chip 100 are bonded to the first peripheral circuit chip 200 and the second peripheral circuit chip 300 respectively.

In some examples, S400 may include: bonding the first peripheral circuit chip 200 to a side of the memory array chip 100 (see FIGS. 4 and 5); and bonding a side of the first peripheral circuit chip 200 far away from the memory array chip 100 to the second peripheral circuit chip 300 (see FIGS. 7 and 8). As an example, in the case that the first peripheral circuit chip 200 includes the first substrate 210 and the first interconnection layer 220, and the memory array chip 100 includes the semiconductor layer 110 and the third interconnection layer 140, bonding the first peripheral circuit chip 200 to a side of the memory array chip 100 may include: bonding the third interconnection layer 140 to the first interconnection layer 220 (see FIGS. 4 and 5); and forming a first interconnection via structure 242 penetrating through the first substrate 210, wherein the first interconnection via structure 242 is connected with the memory array chip 100 through the second interconnection structure 241 (see FIG. 6). As an example, in the case that the second peripheral circuit chip 300 includes a second substrate 310 and a second interconnection layer 320, bonding the side of the first peripheral circuit chip 200 far away from the memory array chip 100 to the second peripheral circuit chip 300 may include: bonding the first substrate 210 to the second interconnection layer 320.

Further, as shown in FIG. 4, bonding the first peripheral circuit chip 200 to a side of the memory array chip 100 may include: forming a second bonding layer 280 on a side of the first interconnection layer 220 facing away from the first substrate 210; forming, in the second bonding layer 280, second bonding contacts 281 penetrating through the second bonding layer 280, wherein the second bonding contacts 281 one-to-one correspond to the first connection structure 240; forming a fourth bonding layer 170 on a side of the third connection layer 140 far away from the third insulation layer 120, wherein fourth bonding contacts 171 corresponding to the first connection structure 240 are formed in the fourth bonding layer 170; and bonding the second bonding layer 280 to the fourth bonding layer 170. As shown in FIG. 9, at this time, the surface of the second bonding layer 280 facing away from the first interconnection layer 220, i.e., a second bonding surface, overlaps with the surface of the fourth bonding layer 170 facing away from the third interconnection layer 140, i.e., a fourth bonding surface. The second connection structure 150, the fourth bonding contacts 171, the second bonding contacts 281 and the first connection structure 240 contact sequentially, and/or the gate layers of the stack structure 130, the fourth bonding contacts 171, the second bonding contacts 281 and the first connection structure 240 contact sequentially.

In some examples, as shown in FIG. 7, bonding the side of the first peripheral circuit chip 200 far away from the memory array chip 100 to the second peripheral circuit chip 300 may include: forming a first bonding layer 270 on a side of the first substrate 210 facing away from the first interconnection layer 220; forming first bonding contacts 271 penetrating through the first bonding layer 270 in the first bonding layer 270, wherein the first bonding contacts 271 one-to-one correspond to and contact with the first connection structure 240; forming a third bonding layer 340 on a side of the second interconnection layer 320 facing away from the second substrate 310; and forming third bonding contacts 341 penetrating through the third bonding layer 340 in the third bonding layer 340, wherein the third bonding contacts 341 correspond to the first connection structure 240 and contact with the third interconnection structure 322. The first bonding layer 270 is in bonding connection with the third bonding layer 340. At this time, the surface of the first bonding layer 270 facing away from the first substrate 210, i.e., a first bonding surface, overlaps with the surface of the third bonding layer 340 facing away from the second interconnection layer 320, i.e., a second bonding surface, and the second device contacts with the first connection structure 240 through the third interconnection structure 322, the third bonding contacts 341, and the first bonding contacts 271 sequentially.

It is to be noted that the materials of the first bonding layer 270 to the fourth bonding layer 170 may include, but are not limited to, insulating materials such as silicon oxide, silicon nitride and/or silicon oxynitride, etc. The materials of the first bonding contacts 271 to the fourth bonding contacts 171 may include, but are not limited to, at least one of tungsten, cobalt, copper, aluminum, and silicide.

In some examples, in order to shorten the depth of the pad structure 160 along the first direction, reduce the process difficulty of forming the pad structure 160, and increase the transmission speed, after performing the operation of bonding the third interconnection layer 140 to the first interconnection layer 220, and before performing the operation of forming the first interconnection via structure 242 penetrating through the first substrate 210, the fabrication method further includes thinning the first substrate 210.

It should be understood that various forms of flows as shown above may be used, and operations thereof may be reordered, added or deleted. As an example, as long as expected results of the technical solutions of the present application can be achieved, various operations set forth in the disclosure may be performed in parallel, in sequence, or in a different order, on which no limitation is imposed herein in this regard.

A peripheral circuit assembly, a memory system and a fabrication method of the memory system provided in implementations of the present application can solve or partially solve deficiencies or needs in prior approaches.

A peripheral circuit assembly provided according to a first aspect of the present application comprises: a first peripheral circuit chip; and a second peripheral circuit chip located on a side of the first peripheral circuit chip along a first direction, wherein one of the first peripheral circuit chip and the second peripheral circuit chip comprises a low low voltage device, and the other one comprises a high voltage device, and the first peripheral circuit chip or the second peripheral circuit chip further includes a controller.

A memory system provided according to a second aspect of the present application comprises: a peripheral circuit assembly that comprises a first peripheral circuit chip and a second peripheral circuit chip located on a side of the first peripheral circuit chip along a first direction, wherein one of the first peripheral circuit chip and the second peripheral circuit chip comprises a low low voltage device, and the other one comprises a high voltage device, and the first peripheral circuit chip or the second peripheral circuit chip further comprises a controller; and at least one memory array chip in bonding connection with at least one of the first peripheral circuit chip and the second peripheral circuit chip along the first direction.

A fabrication method of the memory system provided according to a third aspect of the present application comprises: forming a first peripheral circuit chip comprising a first device; forming a second peripheral circuit chip comprising a second device, wherein one of the first device and the second device comprises a low low voltage device, and the other one comprises a high voltage device, and the first device or the second device further comprises a controller; forming at least one memory array chip; and bonding the at least one memory array chip to at least one of the first peripheral circuit chip and the second peripheral circuit chip along a first direction, wherein the second peripheral circuit chip is located on a side of the first peripheral circuit chip along the first direction.

The peripheral circuit assembly provided by the implementations of the present application may allow the high voltage device and the low low voltage device to no longer affect each other by locating the low low voltage device and the high voltage device on different peripheral circuit chips respectively. In other words, the manufacturing process of the high voltage device is no longer affected by that of the low low voltage device. The high voltage device may employ a large-scale manufacturing process, which not only reduces the process cost, but also enables the polysilicon heights of the high voltage device and the low low voltage device to be unified, and the NP/PP ion implantation of the high voltage device and the low voltage device can also be compatible. At the same time, a thermal budget of the low voltage device is no longer affected by the high voltage device, and there is no need to introduce an additional thermal budget during the fabrication of the low voltage device. In addition, since the first peripheral circuit chip or the second peripheral circuit chip further includes a controller in the implementations of the present application, in other words, the controller and the high voltage device or the low low voltage device are integrated on the same peripheral circuit chip in the implementations of the present application, not only can the cost for forming the controller on a separate wafer be saved, but also the circuit wiring between chips can be reduced, that is, the circuit wiring between the chip where the controller is located and other chips is saved, thereby improving the speed and integration.

According to the memory system provided by the implementations of the present application, the low low voltage device and the high voltage device are disposed on the first peripheral circuit chip and the second peripheral circuit chip respectively, and the first peripheral circuit chip and/or the second peripheral circuit chip are bonded to at least one memory array chip, so that not only the low low voltage device, the high voltage device and the controller may be disposed on the first peripheral circuit chip or the second peripheral circuit chip located on a side of the memory array chip, which increases the number of stacked layers, i.e., the storage density, of the memory array chip without affecting the size of the memory system along a direction vertical to stacking of the memory array chip, thereby achieving the compatibility between the high storage density and the small size of the memory system, but also the low low voltage device and the high voltage device can be located on different peripheral circuit chips respectively, such that the high voltage device and the low low voltage device no longer affect each other. In other words, the manufacturing process of the high voltage device is no longer affected by that of the low low voltage device, the polysilicon heights of the high voltage device and the low low voltage device can also be unified, and the NP/PP ion implantation of the high voltage device and the low voltage device can also be compatible. The high voltage device can employ the large-scale manufacturing process to reduce the process cost; meanwhile, a thermal budget of the low voltage device is no longer affected by the high voltage device, and there is no need to introduce an additional thermal budget during the fabrication of the low voltage device. In addition, since the controller and the high voltage device or the low low voltage device are integrated on the same peripheral circuit chip in the implementations of the present application, not only can the cost of forming the controller on a separate wafer be saved, but also the circuit wiring between chips can be reduced, that is, the circuit wiring between the chip where the controller is located and other chips can be saved, thereby improving the speed and integration.

It is to be understood that the contents as described in this part is neither intended to identify critical or important features of examples of the present application, nor used to limit the scope of the present application.

The above Detailed Description does not constitute a limitation on the protection scope of the present application. Those skilled in the art should understand that various modifications, combinations, sub-combinations and substitutions can be made according to design requirements by equalizing other factors. Any amendments, equivalent substitutions and improvements and the like made within the spirit and principles of the present application shall be included in the protection scope of the present application.

What is claimed is:

1. A peripheral circuit assembly, comprising:
a first peripheral circuit chip; and
a second peripheral circuit chip located on a side of the first peripheral circuit chip along a first direction,
wherein one of the first peripheral circuit chip and the second peripheral circuit chip comprises a low low voltage device, and the other one of the first peripheral circuit chip and the second peripheral circuit chip comprises a high voltage device, and the first peripheral circuit chip or the second peripheral circuit chip further comprises a controller.

2. The peripheral circuit assembly of claim 1, wherein at least one of the first peripheral circuit chip or the second peripheral circuit chip further comprises a low voltage device.

3. The peripheral circuit assembly of claim 2, wherein the first peripheral circuit chip comprises the low low voltage device, the controller and the low voltage device, and the second peripheral circuit chip comprises the high voltage device and the low voltage device.

4. The peripheral circuit assembly of claim 3, wherein the controller is located on a side of the low low voltage device and the low voltage device along a second direction perpendicular to the first direction.

5. The peripheral circuit assembly of claim 1, wherein the peripheral circuit assembly further comprises a third peripheral circuit chip that comprises a low voltage device.

6. A memory system, comprising:
a peripheral circuit assembly that comprises:
a first peripheral circuit chip;
a second peripheral circuit chip located on a side of the first peripheral circuit chip along a first direction, wherein one of the first peripheral circuit chip and the second peripheral circuit chip comprises a low low voltage device, and the other one of the first peripheral circuit chip and the second peripheral circuit chip comprises a high voltage device, and the first peripheral circuit chip or the second peripheral circuit chip further comprises a controller; and
a memory array chip in bonding connection with at least one of the first peripheral circuit chip and the second peripheral circuit chip along the first direction.

7. The memory system of claim 6, wherein at least one of the first peripheral circuit chip or the second peripheral circuit chip further comprises a low voltage device, and the memory array chip comprises a stack structure comprising a core region and a connection region that is located on at least a side of the core region, wherein the low voltage device is disposed corresponding to the core region, and the high voltage device is disposed corresponding to the connection region.

8. The memory system of claim 6, wherein the first peripheral circuit chip is in bonding connection with a side of the memory array chip, and the second peripheral circuit chip is in bonding connection with a side of the first peripheral circuit chip far away from the memory array chip.

9. The memory system of claim 8, wherein the first peripheral circuit chip comprises:
a first substrate;
the low low voltage device and the controller each comprising a transistor that is at least partially located in the first substrate;
a first trench isolation structure disposed in the first substrate and surrounding an active region of the transistor;
a first interconnection layer covering a side of the first substrate and the transistor facing the memory array chip, wherein the transistor is connected with the memory array chip through the first interconnection layer; and
a first connection structure connected with the second peripheral circuit chip at one end, and connected with the memory array chip through the first substrate and the first interconnection layer at the other end.

10. The memory system of claim 9, wherein the first interconnection layer comprises:
a first insulation layer; and
a first interconnection structure located in the first insulation layer, wherein the first interconnection structure is connected with the transistor at one end, and connected with the first connection structure or the memory array chip at the other end.

11. The memory system of claim 8, wherein the second peripheral circuit chip comprises:
a second substrate;
the high voltage device comprising a transistor that is at least partially located in the second substrate;
a second trench isolation structure disposed in the second substrate and surrounding an active region of the transistor; and
a second interconnection layer covering a side of the second substrate and the transistor facing the first peripheral circuit chip, wherein the transistor is connected with the first peripheral circuit chip through the second interconnection layer.

12. The memory system of claim 8, wherein the memory array chip comprises:
a semiconductor layer provided with a pad structure on a side far away from the first peripheral circuit chip;
a third insulation layer disposed on a side of the semiconductor layer facing the first peripheral circuit chip, wherein a stack structure is disposed in the third insulation layer;
a third interconnection layer disposed on a side of the third insulation layer facing the first peripheral circuit chip, wherein the stack structure is connected with the first peripheral circuit chip through the third interconnection layer; and
a second connection structure connected with the pad structure at one end, and connected with the first peripheral circuit chip through the semiconductor layer, the third insulation layer and the third interconnection layer sequentially at the other end.

13. A fabrication method of a memory system, comprising:
forming a first peripheral circuit chip comprising a first device;
forming a second peripheral circuit chip comprising a second device, wherein one of the first device and the second device comprises a low low voltage device, and the other one of the first device and the second device comprises a high voltage device, and the first device or the second device further comprises a controller;
forming at least one memory array chip; and
bonding the at least one memory array chip to at least one of the first peripheral circuit chip and the second peripheral circuit chip along a first direction, wherein the second peripheral circuit chip is located on a side of the first peripheral circuit chip along the first direction.

14. The fabrication method of the memory system of claim 13, wherein bonding the at least one memory array chip to at least one of the first peripheral circuit chip and the second peripheral circuit chip along the first direction comprises:
bonding the first peripheral circuit chip to a side of the memory array chip; and
bonding a side of the first peripheral circuit chip far away from the memory array chip to the second peripheral circuit chip.

15. The fabrication method of the memory system of claim 14, wherein forming the first peripheral circuit chip comprising the first device comprises:
forming the first device based on a side of a first substrate; and
forming a first interconnection layer covering the first device on a side of the first substrate along the first direction, wherein a second interconnection structure penetrating through the first interconnection layer is formed in the first interconnection layer;
wherein forming the at least one memory array chip comprises: forming a third interconnection layer on a side of a semiconductor layer along the first direction;
wherein bonding the first peripheral circuit chip to a side of the memory array chip comprises:
bonding the third interconnection layer to the first interconnection layer; and
forming a first interconnection via structure penetrating through the first substrate, wherein the first interconnection via structure is connected with the memory array chip through the second interconnection structure.

16. The fabrication method of the memory system of claim 15, wherein after performing the bonding the third interconnection layer to the first interconnection layer, and before performing the forming the first interconnection via structure penetrating through the first substrate, the fabrication method further comprises:
thinning the first substrate.

17. The fabrication method of the memory system of claim 15, wherein forming the second peripheral circuit chip comprising the second device comprises:
forming the second device based on a side of a second substrate; and
forming a second interconnection layer covering the second device on a side of the second substrate along the first direction,
wherein bonding the side of the first peripheral circuit chip far away from the memory array chip to the second peripheral circuit chip comprises:
bonding the first substrate to the second interconnection layer.

18. The fabrication method of the memory system of claim 13, wherein the first device comprises the low low voltage device and the controller, and the low low voltage device and the controller each comprises a transistor,
wherein forming the first peripheral circuit chip comprising the first device comprises:
forming the transistor on a first substrate, wherein the transistor is at least partially located in the first substrate;
forming a first trench isolation structure surrounding an active region of the transistor on the first substrate; and
forming a first interconnection layer on the first substrate, wherein the first interconnection layer covers a side of the first substrate on which the transistor is formed and a side of the transistor far away from the first substrate.

19. The fabrication method of the memory system of claim 13, wherein the second device comprises the high voltage device comprising a transistor,
wherein forming the second peripheral circuit chip comprising the second device comprises:
forming the transistor on a second substrate, wherein the transistor is at least partially located in the second substrate;
forming a second trench isolation structure surrounding an active region of the transistor on the second substrate; and
forming a second interconnection layer on the second substrate, wherein the second interconnection layer covers a side of the second substrate on which the transistor is formed and a side of the transistor far away from the second substrate.
